(19) United States
(12) Patent Application Publication
(10) Pub. No.: US 2016/0111669 A1
(43) Pub. Date: Apr. 21, 2016

(54) ORGANIC PHOTOELECTRIC CONVERSION DEVICE AND PRODUCTION METHOD THEREOF

(71) Applicant: SUMITOMO CHEMICAL COMPANY, LIMITED, Tokyo (JP)

(72) Inventor: Yasunori UETANI, Tsukuba-shi (JP)

(73) Assignee: SUMITOMO CHEMICAL COMPANY, LIMITED, Tokyo (JP)

(21) Appl. No.: 14/885,075

(22) Filed: Oct. 16, 2015

(30) Foreign Application Priority Data
Oct. 21, 2014 (JP) 2014-214219

(51) Int. Cl. H01L 51/42; H01L 51/00; H01L 51/44

(52) U.S. Cl. CPC H01L 51/4206; H01L 51/441; H01L 51/0008

(57) ABSTRACT

An organic photoelectric conversion device having an anode, a cathode, an active layer disposed between the anode and the cathode, and a hole injection layer disposed between the anode and the active layer, wherein the cathode is an electrode containing an electrically conductive nano-substance, and the hole injection layer is a layer having a residual film rate of 80% or more in measurement of the residual film rate after water rinse treatment.

### BACKGROUND OF THE INVENTION

1. Field of the Invention

The present invention relates to an organic photoelectric conversion device and a production method thereof. This application is based on Japanese Patent Application No. 2014-214219 filed with Japan Patent Office on Oct. 21, 2014, the content of which are hereby incorporated by reference.

2. Description of the Related Art

An organic photoelectric conversion device used in organic solar batteries, optical sensors and the like are constituted of a pair of electrodes (anode and cathode) and an active layer disposed between the electrodes, and the organic photoelectric conversion device is fabricated by laminating these electrodes, an active layer and the like sequentially in the prescribed order.

For example, a semi-transparent organic photoelectric conversion device is known obtained by coating a solution containing poly(3,4-ethylenedioxythiophene)/poly(4-styrenesulfonic acid) (PEDOT/PSS) on an anode made of ITO to form a hole injection layer, then, coating and forming an active layer, further, coating a coating solution containing nanoparticles of titanium oxide on this active layer to form a functional layer, and further, coating a coating solution containing a silver nano wire as an electrically conductive nano-substance to form a cathode (see, e.g., ACS Nano 2012, vol. 6, no. 8, pp. 7185-7190).

### BRIEF SUMMARY OF THE INVENTION

An organic film solar battery module obtained by integrating an organic photoelectric conversion device is known. As the method for fabricating such an organic film solar battery module, a method in which various layer such as a hole injection layer, an active layer and the like are coated and formed on an anode formed on a substrate, then, these are divided into a plurality of cells by scribing, and thereafter, a cathode is formed is known.

In fabrication of an organic film solar battery module by integrating the known organic photoelectric conversion device by this method, a problem of occurrence of swelling of scribe lines in coating a coating solution containing a silver nano wire after scribing conducted in integration was found.

The present invention relates to an organic photoelectric conversion device having a cathode containing an electrically conductive nano-substance and a production method thereof, and has an object of providing an organic photoelectric conversion device and a production method thereof causing no swelling of scribe lines in fabricating an organic film solar battery module.

The present invention is as described below.

[1] An organic photoelectric conversion device having an anode, a cathode, an active layer disposed between the anode and the cathode, and a hole injection layer disposed between the anode and the active layer, wherein the cathode is an electrode containing an electrically conductive nano-substance, and the hole injection layer is a layer having a residual film rate of 80% or more in measurement of the residual film rate after water rinse treatment shown below:

<Method of Measurement of Residual Film Rate after Water Rinse Treatment>

On a 1-inch square substrate, a film is formed by spin coating so as to give the same film thickness as in the case of film formation as the hole injection layer in the organic photoelectric conversion device, then, a water rinse treatment in which water is placed in the form of meniscus on the film, allowed to stand still for 30 seconds, then, the film is spun at 4000 rpm to fling away water is conducted. The film thicknesses before and after the water rinse treatment are measured by a contact type thickness meter, and (film thickness after water rinse treatment)/(film thickness before water rinse treatment)×100(%) is defined as the residual film rate after water rinse treatment.

[2] The organic photoelectric conversion device according to [1], wherein the electrically conductive nano-substance is at least one nano-substance selected from the group consisting of electrically conductive nanowires, electrically conductive nanotubes and electrically conductive nanoparticles.

[3] The organic photoelectric conversion device according to [1] or [2], having a constitution in which the anode, the hole injection layer, the active layer and the cathode are laminated in this order.

[4] The organic photoelectric conversion device according to any one of [1] to [3], further having a functional layer between the active layer and the cathode.

[5] The organic photoelectric conversion device according to [4], wherein the functional layer is a layer formed by coating a coating solution containing zinc oxide in the form of a particle.

[6] The organic photoelectric conversion device according to any one of [1] to [5], wherein the active layer is a layer formed by a coating method.

[7] The organic photoelectric conversion device according to any one of [1] to [6], wherein the cathode is an electrode formed by coating a coating solution containing water and a nano-substance.

[8] The organic photoelectric conversion device according to any one of [1] to [7], wherein the active layer contains a fullerene and/or a fullerene derivative and a conjugated polymer compound.

[9] An organic film solar battery module having the organic photoelectric conversion device according to any one of [1] to [8].

[10] An organic optical sensor having the organic photoelectric conversion device according to any one of [1] to [8].

[11] A method of producing an organic photoelectric conversion device having a supporting substrate, an anode and a cathode and having a hole injection layer and an active layer between the anode and the cathode, the method comprising a step of forming a hole injection layer on an anode formed on a supporting substrate, a step of forming an active layer on the hole injection layer, and a step of forming a cathode by coating a coating solution containing water and an electrically conductive nano-substance after the step of forming an active layer, wherein the hole injection layer is a layer having a residual film rate of 80% or more in measurement of the residual film rate after water rinse treatment shown below:

<Method of Measurement of Residual Film Rate after Water Rinse Treatment>

On a 1-inch square substrate, a film is formed by spin coating so as to give the same film thickness as in the case of film formation as the hole injection layer in the organic photoelectric conversion device, then, a water rinse treatment in which water is placed in the form of meniscus on the film, allowed to stand still for 30 seconds, then, the film is spun at 4000 rpm to fling away water is conducted. The film thicknesses before and after the water rinse treatment are measured by a contact type thickness meter, and (film thickness after water rinse treatment)/(film thickness before water rinse treatment)×100(%) is defined as the residual film rate after water rinse treatment.

### BRIEF EXPLANATION OF THE DRAWING

FIG. 1 is a schematic cross-sectional view showing an organic film solar battery module as an embodiment of the present invention.

### DESCRIPTION OF THE PREFERRED EMBODIMENTS

The present invention will be illustrated in detail below.

### <1> Constitution of Organic Photoelectric Conversion Device

The organic photoelectric conversion device of the present invention is an organic photoelectric conversion device having an anode, a cathode, an active layer disposed between the anode and the cathode, and a hole injection layer disposed between the anode and the active layer, wherein the cathode is an electrode containing an electrically conductive nano-substance, and the hole injection layer is a layer having a residual film rate of 80% or more in measurement of the residual film rate after water rinse treatment.

The organic photoelectric conversion device of the present invention has preferably a constitution in which an anode, a hole injection layer, an active layer and a cathode are laminated in this order, more preferably a constitution in which a functional layer is further disposed between an active layer and a cathode.

At least one of an anode and a cathode is constituted of a transparent or semi-transparent electrode. An incident light from a transparent or semi-transparent electrode is absorbed in an electron accepting compound and/or an electron donating compound described later in an active layer, thereby generating an exciton biding an electron and a hole. When this exciton moves in an active layer and reaches the hetero junction interface where an electron accepting compound and an electron donating compound are adjacent, electrons and holes separate due to differences of respective HOMO energy and LUMO energy at the interface, and independently movable charges (electrons and holes) are generated. The generated charges move to respective electrodes and extracted outside as electric energy (current).

### (Supporting Substrate)

The organic photoelectric conversion device of the present invention is usually formed on a supporting substrate. As the supporting substrate, those which do not chemically change in fabricating an organic photoelectric conversion device are preferably used. The supporting substrate includes, for example, a glass substrate, a plastic substrate, a polymer film, a silicon plate and the like. In the case of an organic photoelectric conversion device wherein a light is incorporated from a transparent or semi-transparent anode, a highly light-permeable substrate is preferably used as the supporting substrate. When an organic photoelectric conversion device is fabricated on an opaque substrate, a cathode is constituted of a transparent or semi-transparent electrode since a light cannot be incorporated from the anode side. By using such an electrode, a light can be incorporated from a cathode opposite to an anode provided on the supporting substrate side, even if an opaque supporting substrate is used.

When the organic photoelectric conversion device of the present invention is formed on a supporting substrate, the organic photoelectric conversion device of the present invention has preferably a constitution in which a supporting substrate, an anode, a hole injection layer, an active layer and a cathode are laminated in this order, more preferably a constitution in which a functional layer is further disposed between an active layer and a cathode.

### (Anode)

Electrically conductive metal oxide films, metal films, electrically conductive films containing an organic substance, and the like are used as the anode. Specifically, films of indium oxide, zinc oxide, tin oxide, indium tin oxide (Indium Tin Oxide: abbreviated as ITO), indium zinc oxide (Indium Zinc Oxide: abbreviated as IZO), gold, platinum, silver, copper, aluminum, polyaniline and derivatives thereof, polythiophene and derivatives thereof, and the like are used. Of them, films of ITO, IZO and tin oxide are preferably used as the anode. In the case of an organic photoelectric conversion device having a constitution of incorporating a light from an anode, for example, a transparent or semi-transparent electrode obtained by adjusting the thickness of a film constituting an anode described above to a thickness permitting light permeation is used as the anode.

### (Hole Injection Layer)

The hole injection layer is provided between an anode and an active layer, and has a function of promoting injection of holes into an anode. It is preferable that the hole injection layer is disposed in contact with an anode. The hole injection layer contained in the organic photoelectric conversion device of the present invention is a layer which is insoluble in water after film formation. The hole injection layer contained in the organic photoelectric conversion device of the present invention is a layer having a residual film rate of 80% or more, more preferably a residual film rate of 90% or more, further preferably a residual film rate of 98% or more to 100%, in measurement of the residual film rate after water rinse treatment shown below. The thickness of the hole injection layer is usually 1 nm to 100 μm.

In the present invention, the residual film rate after water rinse treatment is determined by the following measurement method. On a 1-inch square substrate, a film is formed by spin coating so as to give the same film thickness as in the case of actual film formation as the hole injection layer in the organic photoelectric conversion device, then, a water rinse treatment in which water is placed in the form of meniscus on the film (film for measurement of residual film rate), allowed to stand still for 30 seconds, then, the film is spun at 4000 rpm to fling away water is conducted on the film. The film thicknesses before and after the water rinse treatment are measured by a contact type thickness meter, and (film thickness after water rinse treatment)/(film thickness before water rinse treatment)×100(%) is defined as the residual film rate after water rinse treatment. In the present invention, measurement was conducted using a contact type thickness meter manufactured by DEKTAK Bruker Nano, as the contact type thickness meter.

The film for measurement of the residual film rate is a film which is substantially the same as the hole injection layer of the organic photoelectric conversion device of the present invention.

More specifically, the film for measurement of the residual film rate is a film produced by using the substantially the same material as for the hole injection layer of the organic photoelectric conversion device of the present invention by substantially the same method as for the hole injection layer and having the substantially the same thickness as that of the hole injection layer.

By placing water in the form of meniscus, namely, so that water forms meniscus, on the film for measurement of the residual film rate, water can be placed so as to cover substantially the whole surface of the film.

Spin for flinging away water can be carried out by a spin coater. Flinging away of water can be visually confirmed. Usually, water can be flung away by spinning at 4000 rpm for 5 seconds or more.

The thicknesses before and after the water rinse treatment is measured at the center part of a 1-inch square substrate.

The material of the hole injection layer contained in the organic photoelectric conversion device of the present invention includes polymer compounds such as polyaniline and derivatives thereof, polythiophene and derivatives thereof, polypyrrole and derivatives thereof, polymer compounds having an aromatic amine residue in the repeating unit, and the like; low molecular weight compounds such as aniline, thiophene, pyrrole, aromatic amine compounds and the like; and inorganic compounds such as CuSCN, CuI and the like. One or more compounds selected from the group consisting of polythiophene and derivatives thereof, aromatic amine compounds, polymer compounds having an aromatic amine residue in the repeating unit, CuSCN and CuI are preferable.

Of polythiophene and derivatives thereof, polythiophene derivatives having a sulfo group are preferable.

### (Active Layer)

The active layer can take a single-layer configuration or a configuration of lamination of a plurality of layers. The active layer having a single-layer constitution is constituted of a layer containing an electron accepting compound and an electron donating compound.

The active layer having a constitution of lamination of a plurality of layers is, for example, constituted of a laminate obtained by laminating a first active layer containing an electron donating compound and a second active layer containing an electron accepting compound. In this case, the first active layer is disposed closer to an anode relative to the second active layer.

The organic photoelectric conversion device may also have a constitution in which a plurality of active layers are laminated via an intermediate layer. In such a case, a multi junction device (tandem device) is obtained. In this case, each active layer may be a single-layer type containing an electron accepting compound and an electron donating compound, or a laminated type constituted of a laminate obtained by laminating a first active layer containing an electron donating compound and a second active layer containing an electron accepting compound.

The intermediate layer can take a single-layer configuration or a configuration of lamination of a plurality of layers. The intermediate layer is constituted of so-called a charge injection layer and/or a charge transporting layer. As the intermediate layer, for example, a functional layer containing an electron transporting material described later can be used.

It is preferable that the active layer is formed by a coating method. The active layer preferably contains a polymer compound, and may contain a polymer compound singly or may contain two or more polymer compounds in combination. For enhancing charge transportability of the active layer, an electron donating compound and/or an electron accepting compound may be mixed in the active layer.

The electron accepting compound used in the organic photoelectric conversion device is composed of a compound having HOMO energy higher than the HOMO energy of an electron donating compound and having LUMO energy higher than the LUMO energy of an electron donating compound.

The electron donating compound may be a low molecular weight compound or a polymer compound. The low molecular weight electron donating compound includes phthalocyanine, metallophthalocyanine, porphyrin, metalloporphyrin, oligothiophene, tetracene, pentacene, rubrene and the like.

The polymer electron donating compound includes polyvinylcarbazole and derivatives thereof, polysilane and derivatives thereof, polysiloxane derivatives having an aromatic amine in the side chain or main chain, polyaniline and derivatives thereof, polythiophene and derivatives thereof, polypyrrole and derivatives thereof, polyphenylenevinylene and derivatives thereof, polythienylenevinylene and derivatives thereof, polyfluorene and derivatives thereof, and the like.

The electron accepting compound may be a low molecular weight compound or a polymer compound. The low molecular weight electron accepting compound includes oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ and the like and derivatives thereof, phenanthrene derivatives such as bathocuproine and the like; etc. The polymer electron accepting compound includes polyvinylcarbazole and derivatives thereof, polysilane and derivatives thereof, polysiloxane derivatives having an aromatic amine in the side chain or main chain, polyaniline and derivatives thereof, polythiophene and derivatives thereof, polypyrrole and derivatives thereof, polyphenylenevinylene and derivatives thereof, polythienylenevinylene and derivatives thereof, polyfluorene and derivatives thereof, and the like. Of them, fullerenes and derivatives thereof are particularly preferable.

The fullerenes include C₆₀, C₇₀, carbon nanotubes and derivatives thereof. Specific structures of the C₆₀ fullerene derivatives include those shown below.

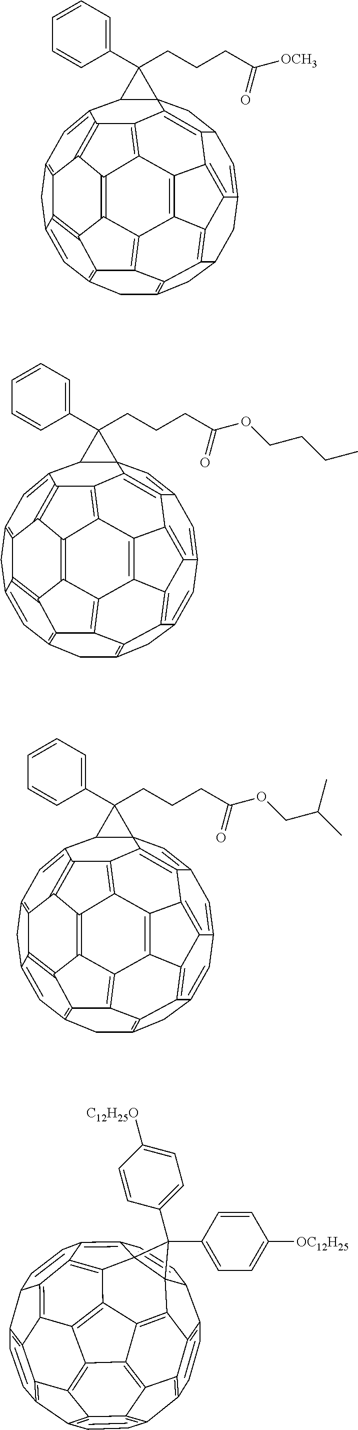

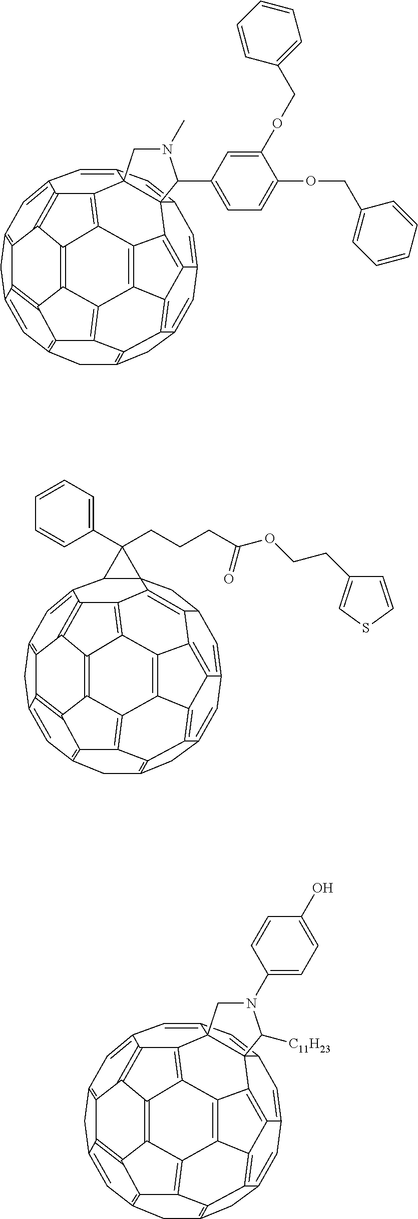

In the active layer having a constitution containing an electron accepting compound composed of a fullerene and/or a fullerene derivative and containing an electron donating compound, the proportion of the fullerene and fullerene derivative is preferably 10 to 1000 parts by weight, more preferably 50 to 500 parts by weight with respect to 100 parts by weight of the electron donating compound. It is preferable that the organic photoelectric conversion device has the active layer having a single-layer constitution, and from the standpoint of considerable inclusion of the hetero junction interface, it is more preferable that the organic photoelectric conversion device has the active layer having a single-layer constitution containing an electron accepting compound composed of a fullerene and/or a fullerene derivative and containing an electron donating compound.

In particular, it is preferable that the active layer contains a conjugated polymer compound and a fullerene and/or a fullerene derivative. The conjugated polymer compound used in the active layer includes polythiophene and derivatives thereof, polyphenylenevinylene and derivatives thereof, polyfluorene and derivatives thereof, conjugated polymer compounds having a constituent unit represented by the formula (I) and the like. Of them, conjugated polymer compounds having a constituent unit represented by the formula (I) are preferable.

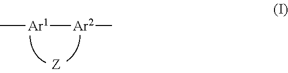

In the formula (I), Z represents a group represented by any one of the following formulae (Z-1) to (Z-7). Ar¹ and Ar² may be the same or different, and represent a tri-valent aromatic heterocyclic group.

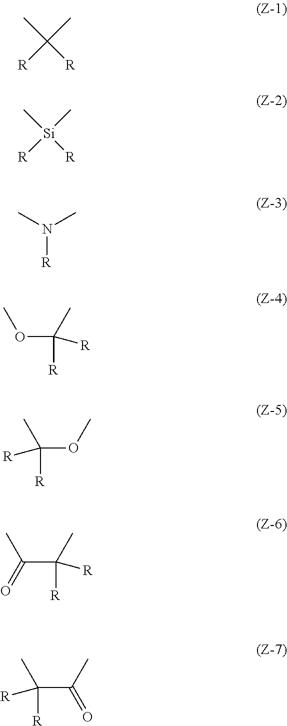

In the formulae (Z-1) to (Z-7), R represents a hydrogen atom, a halogen atom, an amino group, a cyano group or a mono-valent organic group. The mono-valent organic group includes, for example, an optionally substituted alkyl group, an optionally substituted alkoxy group, an optionally substituted alkylthio group, an aryl group, an aryloxy group, an arylthio group, an optionally substituted arylalkyl group, an optionally substituted arylalkoxy group, an optionally substituted arylalkylthio group, an optionally substituted acyl group, an optionally substituted acyloxy group, an optionally substituted amide group, an optionally substituted acid imide group, a substituted amino group, a substituted silyl group, a substituted silyloxy group, a substituted silylthio group, a substituted silylamino group, a mono-valent heterocyclic group, a heterocyclicoxy group, a heterocyclicthio group, an arylalkenyl group, an arylalkynyl group and a carboxyl group. When there are two R in each of the formulae (Z-1) to (Z-7), these may be the same or mutually different.

The constituent unit represented by the formula (I) is preferably a compound represented by the following formula (2).

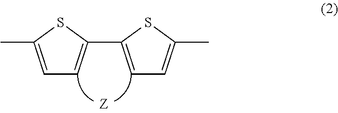

[In the formula (2), Z represents the same meaning as described above.]

The constituent unit represented by the formula (2) includes, for example, constituent units represented by the formulae (501) to (505).

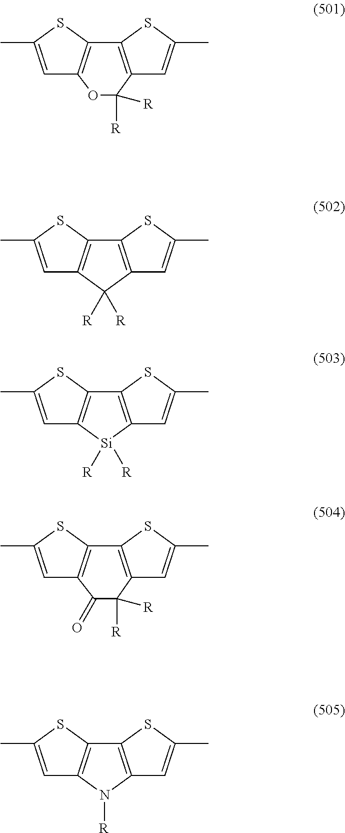

[In the formulae, R represents the same meaning as described above. When there are two R, these may be the same or different.]

Of constituent units represented by the formulae (501) to (505) described above, constituent units represented the formula (501), the formula (502), the formula (503) and the formula (504) are preferable, constituent units represented by the formula (501) and the formula (504) are more preferable, a constituent unit represented by the formula (501) is further preferable, from the standpoint of obtaining a highly efficient photoelectric conversion device.

The conjugated polymer compound having a constituent unit represented by the formula (1) can be produced by a method described in International Publication No. WO2013/051676A1 and can be used.

In the present invention, the polymer compound denotes a compound having a weight-average molecular weight of 3000 or more. The weight-average molecular weight of the polymer compound is preferably 3000 to 10000000, more preferably 8000 to 5000000, further preferably 10000 to 1000000.

When the weight-average molecular weight of the polymer compound is smaller than 3000, coatability may lower in some cases when used for fabrication of a device. When the weight-average molecular weight is larger than 10000000, solubility in a solvent and coatability may lower in some cases when used for fabrication of a device.

The weight-average molecular weight of the polymer compound denotes the polystyrene-equivalent weight-average molecular weight measured by gel permeation chromatography (GPC).

The polystyrene-equivalent number-average molecular weight of the polymer compound is preferably 1000 to 100000000. When the polystyrene-equivalent number-average molecular weight is 1000 or more, a tough film is easily obtained. When the polystyrene-equivalent number-average molecular weight is 100000000 or less, solubility of the polymer compound is high and fabrication of a film is easy. The polystyrene-equivalent number-average molecular weight of the polymer compound is preferably 3000 or more.

The thickness of the active layer is usually 1 nm to 100 μm, preferably 2 nm to 1000 nm, more preferably 5 nm to 500 nm, further preferably 20 nm to 200 nm.

### (Functional Layer)

The organic photoelectric conversion device has sometimes a prescribed functional layer not limited to the active layer, between electrodes. For such a functional layer, it is preferable that a functional layer containing an electron transporting material is disposed between an active layer and a cathode.

It is preferable that the functional layer is formed by a coating method, and for example, it is preferable to form a functional layer by coating a coating solution containing an electron transporting material and a solvent on the surface of a layer on which the functional layer is to be formed. In the present invention, the coating solution includes also dispersions such as an emulsion (milky juice), a suspension (suspending solution) and the like.

The electron transporting material includes, for example, zinc oxide, titanium oxide, zirconium oxide, tin oxide, indium oxide, ITO (indium tin oxide), FTO (fluorine-doped tin oxide), GZO (gallium-doped zinc oxide), ATO (antimony-doped tin oxide) and AZO (aluminum-doped zinc oxide), and of them, zinc oxide, gallium-doped zinc oxide or aluminum-doped zinc oxide is preferable. In forming a functional layer, it is preferable that a coating solution containing granular zinc oxide, gallium-doped zinc oxide or aluminum-doped zinc oxide is coated to form the functional layer. Regarding the electron transporting material as described above, so-called nanoparticles of zinc oxide, gallium-doped zinc oxide or aluminum-doped zinc oxide are preferably used, and it is more preferable to form a functional layer using an electron transporting material composed only of nanoparticles of zinc oxide, gallium-doped zinc oxide or aluminum-doped zinc oxide. The sphere-equivalent average particle size of zinc oxide, gallium-doped zinc oxide or aluminum-doped zinc oxide is preferably 1 nm to 1000 nm, more preferably 10 nm to 100 nm. The average particle size is measured by a laser light scattering method and an X-ray diffraction method.

By providing a functional layer containing an electron transporting material between a cathode and an active layer, peeling of the cathode can be prevented, and efficiency of electron injection from the active layer to the cathode can be enhanced. It is preferable that the functional layer is disposed in contact with an active layer, and it is further preferable that the functional layer is disposed also in contact with a cathode. By providing the functional layer containing an electron transporting material as described above, peeling of the cathode can be prevented, and efficiency of electron injection from the active layer to the cathode can be further enhanced. By providing such a functional layer, an organic photoelectric conversion device which is highly reliable and having high photoelectric conversion efficiency can be realized.

The functional layer containing an electron transporting material functions as so-called an electron transporting layer and/or an electron injection layer. By providing such a functional layer, efficiency of injection of electrons into a cathode can be enhanced, injection of holes from an active layer can be prevented, electron transportability can be enhanced, an active layer can be protected from corrosion by a coating solution used in forming a cathode by a coating method, and deterioration of an active layer can be suppressed.

It is preferable that the functional layer containing an electron transporting material is constituted of a material having high wettability to a coating solution used in coating and forming a cathode. Specifically, it is preferable that the functional layer containing an electron transporting material shows higher wettability to a coating solution than wettability of an active layer to the coating solution used in coating and forming a cathode. By coating and forming a cathode on such a functional layer, a coating solution wets and spreads successfully on the surface of the functional layer in forming a cathode, and a cathode having uniform thickness can be formed.

It is preferable that the coating solution containing an electron transporting material contains at least one selected from the group consisting of complexes of alkali metals, salts of alkali metals, complexes of alkaline earth metals and salts of alkaline earth metals (hereinafter, referred to as “complex or salt of alkali metal and alkaline earth metal” in some cases). By using such a coating solution, a functional layer containing a complex or salt of alkali metal and alkaline earth metal can be formed. By inclusion of a complex or salt of alkali metal and alkaline earth metal, electron injection efficiency can be further enhanced.

It is preferable that the complex or salt of alkali metal and alkaline earth metal is soluble in the solvent of the coating solution. The alkali metal includes lithium, sodium, potassium, rubidium and cesium. The alkaline earth metal includes magnesium, calcium, strontium and barium. The complex includes β-diketone complexes, and the salt includes alkoxides, phenoxides, carboxylates, carbonates and hydroxides.

Specific examples of the complex or salt of alkali metal and alkaline earth metal includes sodium acetylacetonate, cesium acetylacetonate, calcium bis(acetylacetonate), barium bis(acetylacetonate), sodium methoxide, sodium phenoxide, sodium tert-butoxide, sodium tert-pentoxide, sodium acetate, sodium citrate, cesium carbonate, cesium acetate, sodium hydroxide, cesium hydroxide and the like.

Of them, sodium acetylacetonate, cesium acetylacetonate and cesium acetate are preferable.

In the coating solution containing an electron transporting material, the total weight of the complex or salt of alkali metal and alkaline earth metal is 1 to 1000, preferably 5 to 500 when the amount of the granular electron transporting material is 100 parts by weight.

### (Cathode)

The cathode can take a single-layer configuration or a configuration of lamination of a plurality of layers. In the present invention, the cathode contains an electrically conductive nano-substance. The nano-substance means a substance having 1-dimensional, 2-dimensional or 3-dimensional size in nano scale (1000 nm or less). For the nano-substance in the present invention, the 1-dimensional, 2-dimensional or 3-dimensional size is preferably 500 nm or less, more preferably 100 nm or less. The electrically conductive nano-substance includes electrically conductive nanowires, electrically conductive nanotubes, electrically conductive nanoparticles, electrically conductive nanorods, electrically conductive nanoplates and the like. The nanoparticle denotes a nano-substance in which all the three dimensional sizes are in nano scale. For the nanowire, it is preferable that the two dimensional sizes are in nano scale and approximately the same (the ratio of the lengths of the two dimensional sizes is 1:10 or less) and the other one dimensional size is 1000 nm or more. The other one dimensional size is more preferably 2000 nm or more, further preferably 3000 nm or more. The nanotube is a nano-substance having a follow shape, and the preferable size thereof is the same as that of the nanowire. As the nano-substance contained in a cathode, one or more compounds selected from the group consisting of electrically conductive nanowires, electrically conductive nanotubes and electrically conductive nanoparticles are preferable. As the nano-substance, electrically conductive nanowires and/or electrically conductive nanotubes are more preferable, electrically conductive nanowires are further preferable, from the standpoint of light permeability and electrical conductivity. Electrically conductive nanowires and electrically conductive nanotubes get entangled in the form of a lattice, and a transparent electrically conductive film having both light permeability and electrical conductivity can be formed. The coating solution containing an electrically conductive nano-substance and a solvent includes an emulsion (milky juice), a suspension (suspending solution) and the like containing electrically conductive nanoparticles, electrically conductive nanowires or electrically conductive nanotubes. As the solvent used in a coating solution, water is preferably contained since a nano-substance is easily dispersed and an influence of environmental load is reduced. The electrically conductive substance includes metals such as gold, silver and the like, oxides such as ITO (indium tin oxide) and the like, and carbon materials such as graphite, fullerene, carbon nanotubes and the like. The electrically conductive substance is preferably a metal, more preferably silver in the case of electrically conductive nanowires or electrically conductive nanorods. It is preferably a carbon material in the case of electrically conductive nanotubes, electrically conductive nanoparticles and electrically conductive nanoplates. Though the cathode may be constituted only of an electrically conductive nano-substance, the cathode may have a constitution in which these electrically conductive nano-substance are dispersed and placed in a prescribed media such as electrically conductive polymers and the like as shown in Japanese Patent Application National Publication No. 2010-525526.

### <2> Method of Producing Organic Photoelectric Conversion Device

The method of producing an organic photoelectric conversion device of the present invention is method of producing an organic photoelectric conversion device having a pair of electrodes and a hole injection layer and an active layer between the pair of electrodes, the method comprising a step of forming a hole injection layer on an anode formed on a supporting substrate, a step of forming an active layer on the hole injection layer, and a step of forming a cathode by coating a coating solution containing water and an electrically conductive nano-substance after the step of forming an active layer, wherein the hole injection layer is a layer having a residual film rate of 80% or more in measurement of the residual film rate after water rinse treatment.

### <Anode Forming Step>

The anode is formed by forming a film of the anode material exemplified above on the supporting substrate by a vacuum vapor deposition method, a sputtering method, an ion plating method, a plating method and the like. The anode may also be formed by a coating method using a coating solution containing an organic material such as polyaniline and derivatives thereof, polythiophene and derivatives thereof and the like, a metal ink, a metal paste, a low melting point metal in molten state, and the like.

### <Hole Injection Layer Forming Step>

In the present invention, a hole injection layer contained in the organic photoelectronic device can be produced by appropriately selecting constituent materials, production conditions, film thickness and the like.

Though the method of forming a hole injection layer is not particularly restricted, it is preferable to form a hole injection layer by a coating method from the standpoint of simplification of production steps. The hole injection layer can be formed, for example, by a coating method using a coating solution containing a constituent material of the hole injection layer described above and a solvent.

### <Active Layer Forming Step>

Though the method of forming an active layer is not particularly restricted, it is preferable to form an active layer by a coating method from the standpoint of simplification of production steps. The active layer can be formed, for example, by a coating method using a coating solution containing a constituent material of the active layer described above and a solvent, and for example, can be formed by a coating method using a coating solution containing a conjugated polymer compound and a fullerene and/or a fullerene derivative and a solvent.

The solvent includes, for example, hydrocarbon solvents such as toluene, xylene, mesitylene, tetralin, decalin, bicyclohexyl, n-butylbenzene, s-butylbenzene, t-butylbenzene and the like; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like; halogenated unsaturated hydrocarbon solvents such as chlorobenzene, dichlorobenzene, trichlorobenzene and the like; ether solvents such as tetrahydrofuran, tetrahydropyran and the like; etc.

The coating solution used in the present invention may contain two or more kinds of solvents, and may contain two or more kinds of solvents exemplified above.

The method of coating a coating solution containing the constituent material of the active layer includes coating methods such as a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an inkjet printing method, a dispenser printing method, a nozzle coat method, a capillary coat method and the like, and of them, a spin coat method, a flexo printing method, an inkjet printing method and a dispenser printing method are preferable.

### <Functional Layer Forming Step>

As described above, it is preferable to form a functional layer containing an electron transporting material between an active layer and a cathode. That is, it is preferable to form a functional layer by coating a coating solution containing the electron transporting material on an active layer, after formation of the active layer and before formation of the cathode.

When a functional layer containing an electron transporting material is disposed in contact with an active layer, a functional layer is formed by coating the coating solution on the surface of an active layer. In forming a functional layer, it is preferable to use a coating solution imparting little damage on the layer on which the coating solution is to be coated (active layer and the like), and specifically, it is preferable to use a coating solution poorly dissolving the layer on which the coating solution is to be coated (active layer and the like). For example, when a coating solution used in forming a cathode is coated on an active layer, it is preferable to form a functional layer using a coating solution giving smaller damage to the active layer than damage to the active layer by the coating solution, and specifically, it is preferable to form a functional layer using a coating solution showing poorer dissolvability for the active layer than that of a coating solution used in forming a cathode.

The coating solution used in coating and forming a functional layer contains a solvent and the electron transporting material. The solvent of the coating solution includes water, alcohols, ketones and the like, and specific examples of the alcohol include methanol, ethanol, isopropanol, butanol, ethylene glycol, propylene glycol, butoxyethanol, methoxybutanol and the like, specific examples of the ketone include acetone, methyl ethyl ketone, methyl isobutyl ketone, 2-heptanone, cyclohexanone and a mixture composed of two or more of them, and the like. The coating solution used in the present invention may contain two or more kinds of solvents, and may contain two or more kinds of solvents exemplified above.

### <Cathode Forming Step>

The cathode is preferably formed by a coating method using a coating solution containing an electrically conductive nano-substance and a solvent on the surface of an active layer or a functional layer and the like, and in this case, a cathode is formed by coating a coating solution on the surface of an active layer or a functional layer and the like. As the solvent of a coating solution used in forming a cathode of the present invention, water is preferably contained. When water is contained in the solvent, water is contained in a proportion of preferably 10 parts by weight or more, more preferably 50 parts by weight or more with respect to 100 parts by weight of the total weight of the solvent in the coating solution. The other solvent than water which the coating solution may contain includes, for example, hydrocarbon solvents such as toluene, xylene, mesitylene, tetralin, decalin, bicyclohexyl, n-butylbenzene, s-butylbenzene, t-butylbenzene and the like, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like, halogenated unsaturated hydrocarbon solvents such as chlorobenzene, dichlorobenzene, trichlorobenzene and the like, ether solvents such as tetrahydrofuran, tetrahydropyran and the like, alcohols, and the like. Specific examples of the alcohol include methanol, ethanol, isopropanol, butanol, ethylene glycol, propylene glycol, butoxyethanol, methoxybutanol and the like. As the solvent of a coating solution used in the present invention, two or more kinds of solvents may be contained, and two or more kinds of solvents exemplified above may be contained in combination.

In the case of formation of a cathode using a coating solution giving damage on an active layer and a functional layer, it may be permissible that, for example, a cathode is endowed with a two-layer constitution, and a first film is formed using a coating solution not giving damage on an active layer and a functional layer, and then, a second film is formed using a coating solution capable of giving damage on an active layer and a functional layer. By forming a cathode having a two-layer constitution as described above, damage on an active layer and a functional layer can be suppressed since the first film functions as a protective layer even if the second film is formed using a coating solution capable of giving damage on an active layer and a functional layer. For example, when a cathode is formed on a functional layer composed of zinc oxide, a cathode having a two-layer constitution may be formed by forming a first film using a neutral coating solution, then, forming a second film using an acidic solution, since the functional layer composed of zinc oxide is easily damaged by an acidic solution,

In the organic photoelectric conversion device of the present invention, when a transparent or semi-transparent electrode is irradiated with a light such as a solar light and the like, photovoltaic power is generated between electrodes, and the organic photoelectric conversion device can be operated as an organic film solar battery.

By integrating a plurality of the organic photoelectric conversion devices of the present invention, an organic film solar battery module having the organic photoelectric conversion device of the present invention can also be used.

### <Constitution of Organic Film Solar Battery Module>

The organic film solar battery module of the present invention can take basically the same module structure as that of conventional solar battery modules. The organic film solar battery module generally has a structure in which a plurality of organic photoelectric conversion devices (cells) are constituted on a substrate made of metals, ceramics and the like (supporting substrate), the upper side is covered with a filling resin, protective glass and the like, and a light is incorporated from the opposite side of the substrate, however, a structure is also possible in which a transparent material such as reinforced glass and the like is used as a substrate, an organic photoelectric conversion device is constituted on this, and a light is incorporated from the side of the transparent substrate.

Specifically, module structures called a super straight type, a substraight type or a potting type, and substrate-integrated module structures used in amorphous silicon solar batteries and the like are known.

Also the organic film solar battery module of the present invention can appropriately select these module structures depending on the use object, use place and environments.

In typical super straight type or substraight type module structures, organic photoelectric conversion devices are disposed at a regular interval between substrates of which one side or both sides are transparent and having undergone an anti-reflection treatment, and the adjacent organic photoelectric conversion devices are mutually connected by a contact electrode (embedded electrode), metal lead, flexible wiring and the like, a collecting electrode is disposed on the outer periphery, and generated electric power is extracted outside.

Between the substrate and the organic photoelectric conversion device, various kinds of plastic materials such as ethylene vinyl acetate (EVA) and the like may be used in the form of a film or filling resin depending on the object, for protection of the organic photoelectric conversion device and for improvement in power collection efficiency. When used at a place needing no covering of the surface with a hard material such as a place receiving little impact from the outside, the surface protective layer is constituted of a transparent plastic film or the filling resin is hardened to give protective function, and one substrate can be omitted. The periphery of the substrate is fixed in the form of a sandwich by metal frames for confirming interior tight seal and rigidity of a module, and a space between the substrate and the frame is tightly sealed with a sealing material. If a flexible material is used in the organic photoelectric conversion device itself or the substrate, the filling material and the sealing material, it is also possible to constitute an organic photoelectric conversion device on a curved surface.

### <Method of Producing Organic Film Solar Battery Module>

Next, the method of producing an organic film solar battery module having the constitution will be illustrated.

The method of producing an organic film solar battery module of the present invention is a method of producing an organic film solar battery module having a pair of electrodes consisting of a first electrode and a second electrode and an active layer sandwiched between the pair of electrodes, and containing a plurality of organic photoelectric conversion devices disposed on a substrate, and comprises a layer separation step in which one organic film or a laminated structure composed of two or more organic films is cut to form a groove penetrating the one organic film or the laminated structure composed of two or more organic films to expose the surface of a layer located immediately below.

In the case of a solar battery module using a flexible supporting body such as a polymer film and the like, photoelectric conversion devices are formed in sequence on a supporting body while feeding a supporting body in the form of a roll, and cut into desired size, then, peripheral parts are sealed with a flexible material having a moisture-proof property, thus, the module can be fabricated.

A module structure called “SCAF” described in Solar Energy Materials and Solar Cells, 48, pp. 383-391 can also be adopted. Further, the solar battery module using a flexible supporting body can also be adhered and fixed to curved glass and the like and used.

The present invention will be explained in detail below referring to drawings. Since exterior members such as a frame, a protective member and the like in an organic film solar battery module having the constitution are not included in the gist of the present invention, explanations of them are omitted, and the organic photoelectric conversion device and the production method thereof will be chiefly explained.

In the following explanations, the shape, size and layout of a constituent element are shown only schematically in each drawing so that the invention can be roughly understood, and the present invention is not limited by them. In each drawing, the same constituent components are endowed with the same numerals, and duplicate explanations thereof are omitted in some cases.

A first device 100A1 and a second device 100A2 are separated by an inter-device portion 100B not functioning as an organic photoelectric conversion device. A second electrode 24 of the first device 100A1 and a second device 100A2 are electrically connected by a contact (electrode) 24a.

In producing an organic film solar battery module, first, a substrate 10 is prepared. The substrate 10 is a plat substrate having facing two principal surfaces. In preparing the substrate 10, a substrate carrying a previously-formed film of an electrically conductive material capable of acting as an electrode material such as, for example, indium tin oxide may be prepared on one principal surface of the substrate 10.

When a film of an electrically conductive material is not provided on the substrate 10, a film of an electrically conductive material is formed on one principal surface of the substrate 10 by an optional suitable method. Then, the film of an electrically conductive material is patterned. The film of an electrically conductive material is patterned by an optional suitable method such as a photolithography step and an etching step, to form a first electrode (anode) 22 composed of a plurality of patterns mutually electrically separated. By this step, a part of the principal surface of the substrate 10 is exposed in a region of no formation of the first electrode 22.

Next, a first charge transporting layer (hole injection layer) 32 is formed according to an ordinary method on the whole surface of the substrate 10 on which the first electrode 22 has been formed. In the present invention, the first charge transporting layer (hole injection layer) is a layer which is insoluble in water. The constituent materials of a hole injection layer include the same materials as listed in the explanation of an organic photoelectric conversion device.

Then, a first groove X penetrating from the surface of the first charge transporting layer 32 through the first charge transporting layer 32 to expose the surface of the substrate 10 is formed by a scribe processing and the like, in a region existing in an inter-device portion 100 B and between a plurality of first electrodes (patterns) 22. By formation of this first groove X, the first electrode 22 of the first device 100A1 and the first electrode 22 of the second device 100A2 are dissociated by the first groove X and electrically separated (first layer separation step).

Subsequently, an active layer 40 covering the first charge transporting layer 32 is formed. The active layer 40 can be formed by coating a coating solution, for example, by a coating method such as a spin coat method.

Next, a second charge transporting layer (functional layer) 34 covering the active layer 40 is formed. Subsequently, a second groove Y penetrating from the surface of the second charge transporting layer 34 through the second charge transporting layer 34, the active layer 40 and the first charge transporting layer 32, reaching the surface of the first electrode 22 of the second device 100A2, in an inter-device portion 100B, is formed by a scribe processing and the like (second layer separation step). This second groove Y is used as a contact groove (or contact hole) for electrically connecting the second electrode 24 of the first device 100A1 and the first electrode of the second device 100A2. Therefore, in a precise sense, the second groove Y may not have a constitution bisecting the active layer 40 and the first charge transporting layer 32 on the first electrode 22.

Next, a contact (electrode) 24a coveting the second charge transporting layer 34 and plugging the second groove Y, to contact the first electrode 22, is formed. The contact 24a causes conduction of the second electrode (cathode) 24 of the first device 100A1 and the first electrode (anode) 22 of the second device 100A2.

Since the second groove Y has a structure for contact causing conduction of the first electrode 22 and the second electrode 24 as described above, its shape can be a pillared shape such as a groove and a column and is not particularly restricted, and in this example, an example of formation of a groove will be explained.

By forming the contact 24a as described above, adjacent organic photoelectric conversion devices are mutually electrically connected, and an organic film solar battery module in which a plurality of organic photoelectric conversion devices are mutually connected is produced.

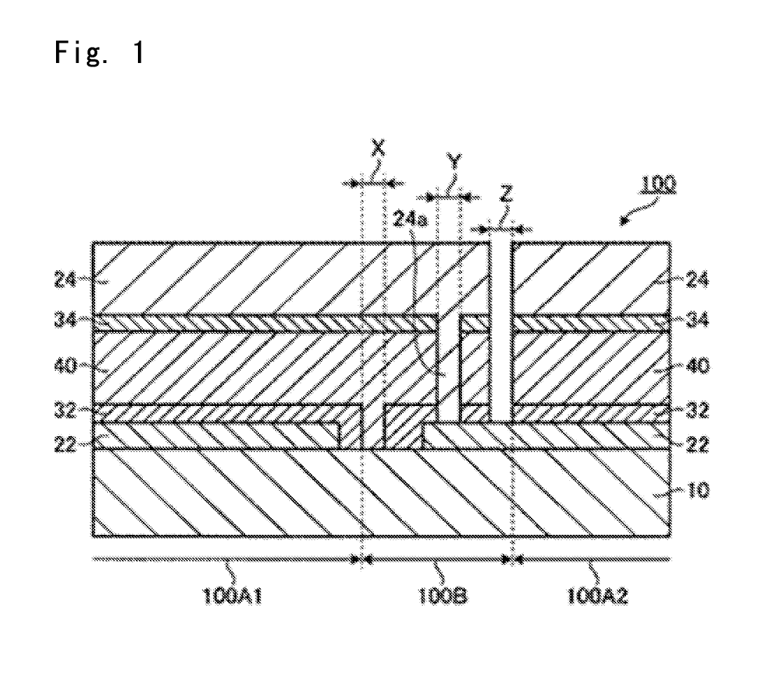

In the present invention, it is preferable that the second electrode 24 (cathode) and the contact 24a are formed by coating a coating solution containing an electrically conductive nano-substance and a solvent, after formation of the contact groove (Y) in FIG. 1 in a layer separation step. It is preferable that the coating solution contains water. The electrically conductive nano-substance includes the same nano-substances as the nano-substances explained for an organic photoelectric conversion device.

The first charge transporting layer 32, the active layer 40 and the second charge transporting layer 34 can be formed by drying a layer formed by a coating method using a coating solution, under conditions suitable for the material and the solvent, under an optional suitable atmosphere such as a nitrogen gas atmosphere.

As the film formation method, coating methods such as a spin coat method, a casting method, a micro gravure coat method, a gravure coat method, a bar coat method, a roll coat method, a wire bar coat method, a dip coat method, a spray coat method, a screen printing method, gravure printing, a flexo printing method, an offset printing method, an inkjet printing method, a dispenser printing method, a nozzle coat method, a capillary coat method and the like can be used, and preferable are a spin coat method, a flexo printing method, a gravure printing method, an inkjet printing method and a dispenser printing method.

The solvent used in these film formation methods using a solution is not particularly restricted, providing it dissolves the material of each layer and it is not repelled by a liquid-repellent pattern to wet and spread on the liquid-repellent pattern.

Such a solvent includes, for example, unsaturated hydrocarbon solvents such as toluene, xylene, mesitylene, tetralin, decalin, bicyclohexyl, n-butylbenzene, sec-butylbenzene, tert-butylbenzene and the like, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like, halogenated unsaturated hydrocarbon solvents such as chlorobenzene, dichlorobenzene, trichlorobenzene and the like, and ether solvents such as tetrahydrofuran, tetrahydropyran and the like.

Next, a third groove Z penetrating from the surface of the second electrode 24 through the second electrode 24, the second charge transporting layer 34, the active layer 40 and the first charge transporting layer 32 to expose a part of the first electrode 22 existing outside of the liquid-repellent pattern 30a in the inter-device portion 100B is formed (third layer separation step).

The third groove Z is a constitution for electrically separating the first device 100A1 and the second device 100A2 by the inter-device portion 100B. By forming the third groove Z, a plurality of organic photoelectric conversion devices are formed by device separation. The inter-device portion 100B is in the form of a line groove, and in this example, splits adjacent devices along the shape of the periphery (in this example, linear) around the peripheral part of the first electrode 22. Since the inter-device portion 100B is a region not functioning as a photoelectric conversion device, it is recommendable that the portion is as small as possible. Therefore, it is advantageous that the third groove Z is formed to give the shape and the layout position by which the size of the inter-device portion 100B can be reduced as much as possible. For example, in this example, it is advantageous that the third groove is formed as a linear groove which is close as much as possible to the periphery of the first electrode 22 and which is narrow as much as possible.

By irradiating a transparent or semi-transparent electrode with a light under condition of application of voltage between electrodes, photocurrent flows, and the organic photoelectric conversion device of the present invention can be operated as an organic optical sensor. By integrating a plurality of organic optical sensors, an organic image sensor can also be obtained and used.

### EXAMPLES

Examples will be shown below for illustrating the present invention further in detail, but the present invention is not limited to them.

In the following examples, the polystyrene-equivalent number-average molecular weight and weight-average molecular weight were determined using GPC manufactured by GPC Laboratory Co., Ltd. (PL-GPC2000) as the molecular weight of a polymer. The polymer was dissolved in o-dichlorobenzene so that the concentration of the polymer was about 1 wt %. As the mobile phase of GPC, o-dichlorobenzene was used, and the solution was flowed at a flow rate of 1 mL/minute at a measuring temperature of 140° C. As the column, three columns of PLGEL 10 μm MIXED-B (manufactured by PL Laboratory) were connected serially.

### Synthesis Example 1

### Synthesis of Compound 2

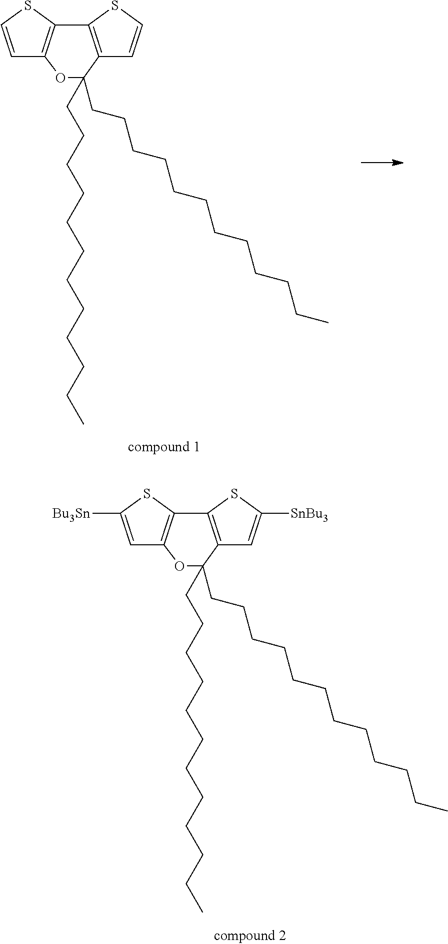

Into a 200 mL flask of which gas in the flask had been purged with argon were charged 2.00 g (3.77 mmol) of a compound 1 synthesized according to a description of International Publication No. 2011/052709 and 100 mL of dehydrated tetrahydrofuran, and a uniform solution was prepared. While keeping the solution at −78° C., 5.89 mL (9.42 mmol) of a 1.6 M n-butyllithium hexane solution was dropped into the solution over a period of 10 minutes. After dropping, the reaction solution was stirred at −78° C. for 30 minutes, then, stirred at room temperature (25° C.) for 2 hours. Thereafter, the flask was cooled down to −78° C., and to the reaction solution was added 3.37 g (10.4 mmol) of tributyltin chloride. After addition, the reaction solution was stirred at −78° C. for 30 minutes, then, stirred at room temperature (25° C.) for 3 hours. Thereafter, to the reaction solution was added 200 ml of water to stop the reaction, and ethyl acetate was added and the organic layer containing the reaction product was extracted. The organic layer was dried over sodium sulfate, filtrated, then, the filtrate was concentrated by an evaporator to distill off the solvent. The resultant oily substance was purified by a silica gel column using hexane as a developing solvent. As the silica gel in the silica gel column, silica gel previously immersed in hexane containing 10 wt % trimethylamine for 5 minutes, then, rinsed with hexane was used. After purification, 3.55 g (3.20 mmol) of a compound 2 was obtained.

### Synthesis Example 2

### Synthesis of Polymer Compound 1

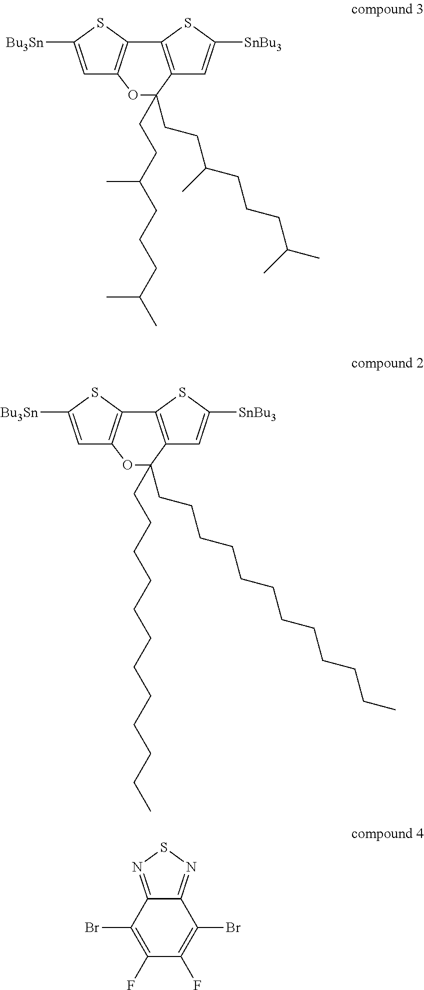

Into a 300 mL flask of which gas in the flask had been purged with argon were charged 800 mg (0.760 mmol) of a compound 3 synthesized according to a description of International Publication No. 2011/052709, 840 mg (0.757 mmol) of a compound 2, 471 mg (1.43 mmol) of a compound 4 synthesized according to a description of International Publication No. 2011/052709 and 107 ml of toluene, and a uniform solution was prepared. The resultant toluene solution was bubbled with argon for 30 minutes. Thereafter, to the toluene solution were added 19.6 mg (0.0214 mmol) of tris(dibenzylideneacetone)dipalladium and 39.1 mg (0.128 mmol) of tris(2-toluyl)phosphine, and the mixture was stirred at 100° C. for 6 hours. Thereafter, to the reaction solution was added 660 mg of phenyl bromide, and the mixture was further stirred for 5 hours. Thereafter, the flask was cooled down to 25° C., and the reaction solution was poured into 2000 mL of methanol. The deposited polymer was filtrated and collected, the resultant polymer was placed into a cylindrical paper filter, and extracted with methanol, acetone and hexane each for 5 hours using a Soxhlet extractor. The polymer remaining in the cylindrical paper filter was dissolved in 53 mL of o-dichlorobenzene, and 1.21 g of sodium diethyldithiocarbamate and 12 mL of water were added, and the mixture was stirred for 8 hours under reflux. The aqueous layer was removed, then, the organic layer was washed with 200 ml of water twice, then, washed with 200 mL of a 3 wt % acetic acid aqueous solution twice, then, washed with 200 mL of water twice, and the resultant solution was poured into methanol to cause deposition of a polymer. The polymer was filtrated, then, dried, and the resultant polymer was dissolved again in 62 mL of o-dichlorobenzene, and the solution was allowed to pass through an alumina/silica gel column. The resultant solution was poured into methanol to cause deposition of a polymer, the polymer was filtrated, then, dried, to obtain 802 mg of a purified polymer. Hereinafter, this polymer is called a polymer compound 1.

### (Production of Composition 1)

Ten (10) parts by weight of [6,6]-phenyl C61-butyric acid methyl ester (C60PCBM) (E100 manufactured by Frontier Carbon) as the fullerene derivative, 5 parts by weight of the polymer 1 as the electron-donating compound, and 1000 parts by weight of o-dichlorobenzene as the solvent were mixed. Next, the mixed solution was filtrated through a Teflon (registered trademark) filter having a pore diameter of 1.0 μm, to prepare a composition 1.

### Example 1

### Fabrication and Evaluation of Organic Film Solar Battery

A glass substrate carrying thereon a formed ITO film functioning as an anode of a solar battery was prepared. The ITO film had been formed by a sputtering method, and its thickness was 150 nm. This glass substrate was subjected to an ozone UV treatment, to surface-treat the ITO film. Next, Plexcore PV2000 Hole Transport Ink (purchased from Sigma-Aldrich. Sulfonated polythiophene (thiophene-3-[2-(2-methoxyethoxy)ethoxy]-2,5-diyl) (S-P3MEET) 1.8% in 2-butoxyethanol:water (2:3)) was coated on the ITO film by spin coat, and heated in atmospheric air at 170° C. for 10 minutes, to form a hole injection layer having a thickness of 50 nm. On this hole injection layer, the composition 1 was coated by spin coat, to form an active layer (thickness: about 100 nm).

Next, a 45 wt % isopropanol dispersion of zinc oxide nanoparticles (HTD-711Z, manufactured by Tayca Corporation) was diluted with isopentanol in an amount of 10-fold parts by weight of the dispersion, to prepare a coating solution. This coating solution was coated with a thickness of 70 nm on an active layer, to form a functional layer.

Next, for obtaining contact of a cathode to be fabricated later with a leading ITO electrode, the coated film formed up to a functional layer was scribed with tweezers, and the leading electrode surface was exposed.

Next, a wire-shaped electric conductor dispersion in a water solvent (ClearOhm (registered tradename) Ink-N AQ: manufactured by Cambrios Technologies Corporation) was coated by a spin coater, and dried, to obtain a cathode composed of an electrically conductive wire layer having a thickness of 120 nm. Thereafter, an organic film solar battery was obtained by sealing with an UV curable sealant. A 1 cm×1 cm regular tetragonal shielding mask was covered on the resultant organic film solar battery, and the resultant organic film solar battery was irradiated with a constant light using Solar Simulator (manufactured by BUNKOUKEIKI Co., Ltd., trade name: OTENTO-SUNII: AM 1.5G filter, irradiance: 100 mW/cm²), and the photoelectric conversion efficiency was determined by measuring generating current and voltage. The photoelectric conversion efficiency was 2.43%, the current density was 9.54 mA/cm², the open end voltage was 0.66 V and FF (fill factor) was 0.39. When scribe lines were observed, no swelling of scribe lines was found at all.

### Comparative Example 1

### Fabrication and Evaluation of Organic Film Solar Battery

A glass substrate carrying thereon a formed ITO film functioning as an anode of a solar battery was prepared. The ITO film had been formed by a sputtering method, and its thickness was 150 nm. This glass substrate was subjected to an ozone UV treatment, to surface-treat the ITO film. Next, a PEDOT:PSS solution (CleviosP VP AI4083 manufactured by Heraeus) was coated on the ITO film by spin coat, and heated in atmospheric air at 120° C. for 10 minutes, to form a hole injection layer having a thickness of 50 nm. On this hole injection layer, the composition 1 was coated by spin coat, to form an active layer (thickness: about 100 nm).

Next, a 45 wt % isopropanol dispersion of zinc oxide nanoparticles (HTD-711Z, manufactured by TAYCA Corporation) was diluted with isopentanol in an amount of 10-fold parts by weight of the dispersion, to prepare a coating solution. This coating solution was coated with a thickness of 70 nm on an active layer by spin coat, to form a functional layer.

Next, to obtain contact of a cathode to be fabricated later with a leading ITO electrode, the coated film formed up to a functional layer was scribed with tweezers, to expose the leading electrode surface.

Next, a wire-shaped electric conductor dispersion in a water solvent (ClearOhm (registered tradename) Ink-N AQ: manufactured by Cambrios Technologies Corporation) was coated by a spin coater, and dried, to obtain a cathode composed of an electrically conductive wire layer having a thickness of 120 nm. Thereafter, an organic film solar battery was obtained by sealing with an UV curable sealant. A 1 cm×1 cm regular tetragonal shielding mask was covered on the resultant organic film solar battery, and the resultant organic film solar battery was irradiated with a constant light using Solar Simulator (manufactured by BUNKOUKEIKI Co., Ltd., trade name: OTENTO-SUNII: AM 1.5G filter, irradiance 100 mW/cm²), and the photoelectric conversion efficiency was determined by measuring generating current and voltage. The photoelectric conversion efficiency was 2.16%, the short circuit current density was 9.09 mA/cm², the open end voltage was 0.64 V and FF (fill factor) was 0.37. When scribe lines were confirmed, swelling believed to be caused by invasion of water was observed in scribe lines.

### (Measurement of Residual Film Rate)

On a 1-inch square substrate, Plexcore PV2000 Hole Transport Ink (purchased from Sigma-Aldrich) was coated by spin coat, and heated in atmospheric air at 170° C. for 10 minutes, to form a coated film of a hole injection layer having a thickness of 50 nm. Next, a water rinse treatment in which water is placed in the form of meniscus on this coated film, and after 30 seconds, the film is spun at 4000 rpm to fling away water was conducted. The residual film rate after water rinse treatment of the coated film was 100%.

On a 1-inch square substrate, a PEDOT:PSS solution (CleviosP VP AI4083 manufactured by Heraeus) was coated by spin coat, and heated in atmospheric air at 120° C. for 10 minutes, to form a coated film of a hole injection layer having a thickness of 50 nm. Next, a water rinse treatment in which water is placed in the form of meniscus on this coated film, and after 30 seconds, the film is spun at 4000 rpm to fling away water was conducted. The residual film rate after water rinse treatment of the coated film was 0%.

### Comparative Example 2

### Fabrication and Evaluation of Organic Film Solar Battery

A glass substrate carrying thereon a formed ITO film functioning as an anode of a solar battery was prepared. The ITO film had been formed by a sputtering method, and its thickness was 150 nm. This glass substrate was subjected to an ozone UV treatment, to surface-treat the ITO film. Next, a PEDOT:PSS solution (CleviosP VP AI4083 manufactured by Heraeus) was coated on the ITO film by spin coat, and heated in atmospheric air at 200° C. for 10 minutes, to form a hole injection layer having a thickness of 50 nm. On this hole injection layer, the composition 1 was coated by spin coat, to form an active layer (thickness: about 140 nm).

Next, a 45 wt % isopropanol dispersion of zinc oxide nanoparticles (HTD-711Z, manufactured by TAYCA Corporation) was diluted with isopentanol in an amount of 10-fold parts by weight of the dispersion, to prepare a coating solution. This coating solution was coated with a thickness of 70 nm on an active layer by spin coat, to form a functional layer.

Next, to obtain contact of a cathode to be fabricated later with a leading ITO electrode, the coated film formed up to a functional layer was scribed with tweezers, to expose the leading electrode surface.

Next, a wire-shaped electric conductor dispersion in a water solvent (ClearOhm (registered tradename) Ink-N AQ: manufactured by Cambrios Technologies Corporation) was coated by a spin coater, and dried, to obtain a cathode composed of an electrically conductive wire layer having a thickness of 120 nm. Thereafter, an organic film solar battery was obtained by sealing with an UV curable sealant. A 1 cm×1 cm regular tetragonal shielding mask was covered on the resultant organic film solar battery, and the resultant organic film solar battery was irradiated with a constant light using Solar Simulator (manufactured by BUNKOUKEIKI Co., Ltd., trade name: OTENTO-SUNII: AM 1.5G filter, irradiance 100 mW/cm²), and the photoelectric conversion efficiency was determined by measuring generating current and voltage. The photoelectric conversion efficiency was 2.16%, the short circuit current density was 10.15 mA/cm², the open end voltage was 0.66 V and FF (fill factor) was 0.32. When scribe lines were confirmed, swelling believed to be caused by invasion of water was observed in scribe lines.

### (Measurement of Residual Film Rate)

On a 1-inch square substrate, a PEDOT:PSS solution (CleviosP VP A14083 manufactured by Heraeus) was coated by spin coat, and heated in atmospheric air at 200° C. for 10 minutes, to form a coated film of a hole injection layer having a thickness of 50 nm. Next, a water rinse treatment in which water is placed in the form of meniscus on this coated film, and after 30 seconds, the film is spun at 4000 rpm to fling away water was conducted. The residual film rate after water rinse treatment of the coated film was 24%.

According to the present invention, an organic photoelectric conversion device causing no swelling of scribe lines in fabricating an organic film solar battery module is provided. By using the organic photoelectric conversion device of the present invention, swelling of scribe lines can be prevented in forming a cathode by coating a coating solution containing water and an electrically conductive nano-substance in fabrication of an organic film solar battery module. By using the organic photoelectric conversion device of the present invention, it is possible to prevent lowering of photoelectric conversion efficiency generated by forming a cathode by coating a coating solution containing water and an electrically conductive nano-substance in fabrication of an organic film solar battery module.

### EXPLANATION OF NUMERALS

10: substrate
22: first electrode
24: second electrode
24a: contact
32: first charge transporting layer
34: second charge transporting layer
40: active layer
100: organic film solar battery module
100A1: first device
100A2: second device
100B: inter-device portion
X: first groove
Y: second groove
Z: third groove

1. An organic photoelectric conversion device having an anode, a cathode, an active layer disposed between the anode and the cathode, and a hole injection layer disposed between the anode and the active layer, wherein the cathode is an electrode containing an electrically conductive nano-substance, and the hole injection layer is a layer having a residual film rate of 80% or more in measurement of the residual film rate after water rinse treatment shown below:
<Method of measurement of residual film rate after water rinse treatment>
On a 1-inch square substrate, a film is formed by spin coating so as to give the same film thickness as in the case of film formation as the hole injection layer in the organic photoelectric conversion device, then, a water rinse treatment in which water is placed in the form of meniscus on the film, allowed to stand still for 30 seconds, then, the film is spun at 4000 rpm to fling away water is conducted. The film thicknesses before and after the water rinse treatment are measured by a contact type thickness meter, and (film thickness after water rinse treatment)/(film thickness before water rinse treatment)×100(%) is defined as the residual film rate after water rinse treatment.

2. The organic photoelectric conversion device according to claim 1, wherein the electrically conductive nano-substance is at least one nano-substance selected from the group consisting of electrically conductive nanowires, electrically conductive nanotubes and electrically conductive nanoparticles.

3. The organic photoelectric conversion device according to claim 1, having a constitution in which the anode, the hole injection layer, the active layer and the cathode are laminated in this order.

4. The organic photoelectric conversion device according to claim 1, further having a functional layer between the active layer and the cathode.

5. The organic photoelectric conversion device according to claim 4, wherein the functional layer is a layer formed by coating a coating solution containing zinc oxide in the form of a particle.

6. The organic photoelectric conversion device according to claim 1, wherein the active layer is a layer formed by a coating method.

7. The organic photoelectric conversion device according to claim 1, wherein the cathode is an electrode formed by coating a coating solution containing water and a nano-substance.

8. The organic photoelectric conversion device according to claim 1, wherein the active layer contains a fullerene and/or a fullerene derivative and a conjugated polymer compound.

9. An organic film solar battery module having the organic photoelectric conversion device according to claim 1.

10. An organic optical sensor having the organic photoelectric conversion device according to claim 1.

11. A method of producing an organic photoelectric conversion device having a supporting substrate, an anode and a cathode and having a hole injection layer and an active layer between the anode and the cathode, the method comprising a step of forming a hole injection layer on an anode formed on a supporting substrate, a step of forming an active layer on the hole injection layer, and a step of forming a cathode by coating a coating solution containing water and an electrically conductive nano-substance after the step of forming an active layer, wherein the hole injection layer is a layer having a residual film rate of 80% or more in measurement of the residual film rate after water rinse treatment shown below:
<Method of measurement of residual film rate after water rinse treatment>
On a 1-inch square substrate, a film is formed by spin coating so as to give the same film thickness as in the case of film formation as the hole injection layer in the organic photoelectric conversion device, then, a water rinse treatment in which water is placed in the form of meniscus on the film, allowed to stand still for 30 seconds, then, the film is spun at 4000 rpm to fling away water is conducted. The film thicknesses before and after the water rinse treatment are measured by a contact type thickness meter, and (film thickness after water rinse treatment)/(film thickness before water rinse treatment)×100(%) is defined as the residual film rate after water rinse treatment.
